(19) United States
(12) Patent Application Publication
(10) Pub. No.: US 2012/0050977 A1
(43) Pub. Date: Mar. 1, 2012

(54) Detachable External Hard Drive Enclosure and Bridge Device Therefor

(76) Inventor: Ping-Hung Lai, Yonghe (TW)

(21) Appl. No.: 12/870,905

(22) Filed: Aug. 30, 2010

(51) Int. Cl. H05K 5/00; G06F 1/16

(52) U.S. Cl. 361/679.33

(57) ABSTRACT

A detachable external hard drive enclosure has a hard drive box for receiving a hard drive, a bridge device and an engagement mechanism. The hard drive box has a front opening. The bridge device has a hard drive port for engaging the hard drive. The engagement mechanism is formed on the hard drive box and the bridge device. When the bridge device is connected to or disconnected from the front opening of the hard drive box with the engagement mechanism, the hard drive port can engage or disengage from the hard drive. Accordingly, the bridge device can engage and disengage from the hard drive box to conveniently replace various hard drives.

### BACKGROUND OF THE INVENTION

1. Field of the Invention

The present invention is related to an external hard drive enclosure, and more particularly to a detachable external hard drive enclosure having a bridge device capable of engaging and being compatible with hard drive boxes having different sizes.

2. Description of the Related Art

With reference to FIGS. 8 and 9, a conventional external hard drive enclosure has a case 40, a rectangular bracket 43 and a bridge device 50. The case 40 is rectangular and hollow and has a front opening 41 and two screw holes 42. The front opening 41 is formed through a front side of the case 40. The two screw holes 42 are formed through two other opposite sides of the case 40.

The rectangular bracket 43 is received in the case 40 and has a side corresponding to the front opening 41 of the case 40 and fixed with a hard drive 60.

The bridge device 50 has a control panel 51 and a circuit board 53. The control panel 51 and the circuit board 53 are securely mounted on the side of the rectangular bracket 43 corresponding to the front opening 41 of the case 40. The circuit board 53 has a hard drive port 511, a computer port 512 and a power input port 513. The computer port 512 and the power input port 513 are formed and exposed from a side of the control panel 51 facing outside. The hard drive port 511 is formed on the side of the rectangular bracket 43 corresponding to the front opening 41 of the case 40.

With reference to FIG. 10, a hard drive 60 is mounted in the rectangular bracket 43, plugged in the hard drive port 511 and fixed on the rectangular bracket 43. The rectangular bracket 43 along with the circuit board 53 of the bridge device 50 are inserted in the front opening 41 of the case 40 so that the control panel 51 is covered on the front opening 41 of the case 40. Two screws 54 screw the rectangular bracket 43 respectively through the two screw holes 42 of the case 40 so that the rectangular bracket 43 and the bridge device 50 are fastened with the case 40. If intending to remove and replace the hard drive 60, the two screws 54 must be unscrewed first. After the bridge device 50 and the rectangular bracket 43 are pulled out from the front opening 41 of the case 40, the hard drive 60 is unplugged from the hard drive port 511. A different hard drive 60 can be mounted again by repeating the foregoing assembling procedures.

Although the conventional external hard drive enclosure serves to externally connect with a computer, it is inconvenient to replace the hard drive in the conventional external hard drive enclosure. Besides, the case and the rectangular bracket may not be compatible with a hard drive to be replaced with having a different size. For example, an external hard drive enclosure for 3.5″ hard drive is not compatible with a 2.5″ hard drive, and vice versa.

### SUMMARY OF THE INVENTION

A first objective of the present invention is to provide a detachable external hard drive enclosure having a bridge device capable of engaging and being compatible with hard drive boxes having different sizes.

To achieve the foregoing objective, the detachable external hard drive enclosure has hard drive box, a bridge device, and an engagement mechanism.

The hard drive box has a front opening formed through a side of the hard drive box and is adapted to receive a hard drive in the hard drive box.

The bridge device has a housing, a control circuit board, a hard drive port, at least one computer port, a power input port and an engagement mechanism.

The housing has a first side and a second side facing to the front opening and being opposite to the first side. The control circuit board is mounted inside the housing. The hard drive port is mounted inside the housing and protrudes beyond the second side of the housing, and is electrically connected with the control circuit board. The at least one computer port is mounted inside the housing and protrudes beyond the first side of the housing, and is electrically connected with the control circuit board. The power input port is mounted inside the housing and protrudes beyond the first side of the housing, and is electrically connected with the control circuit board.

The engagement mechanism is mounted on the side of the hard drive box having the front opening and the second side of the bridge device for the bridge device to engage the hard drive box.

The bridge device is detachable from the hard drive box and engages the hard drive box with the engagement mechanism instead of being securely connected with the hard drive box by means of screws. The hard drive port of the bridge device faces the front opening of the hard drive box, and can be electrically connected with the hard drive in the hard drive box. Accordingly, the detachable external hard drive enclosure of the present invention is convenient and easy to replace a hard drive in the hard drive box.

A second objective of the present invention is to provide a bridge device for an external hard drive box capable of being detachable from a hard drive box through an engagement mechanism.

To achieve the foregoing objective, the external hard drive box has a front opening and the bridge device has a housing, a control circuit board, a hard drive port, a computer port, a power input port and an engagement mechanism.

The housing is adapted to connect with the front opening of the external hard drive box and engage the detachable external hard drive enclosure, and has a first side, a second side and three through holes. The second side faces to the front opening and is opposite to the first side. Two of the through slots are formed through the first side and one of the through holes is formed through the second side of the housing.

The control circuit board is mounted inside the housing.

The hard drive port is mounted inside the housing, is electrically connected with the control circuit board, protrudes beyond the housing through the through slot on the second side, and is adapted to connect with an electrical connector of an external hard drive.

The at least one computer port is mounted inside the housing, is electrically connected with the control circuit board, protrudes beyond the housing through one of the through slots on the first side, and is adapted to connect with an external computer.

The power input port is mounted inside the housing, is electrically connected with the control circuit board, protrudes beyond the housing through the other of the through slots on the first side, and is adapted to connect with an external power source to supply an operating power to the control circuit.

The engagement mechanism is mounted on the second side of the housing and is adapted to connect with the hard drive box.

Given the engagement mechanism mounted on the side of the bridge device beyond which the computer port protrudes, the bridge device can directly engage the hard drive box and the computer port is connected to the hard drive without involving with unscrewing and screwing the bridge device and the hard drive box, thereby facilitating the replacement of the hard drive. Besides, as long as the hard drive therein has an interface compatible with the computer port of the bridge device, the bridge device can engage the hard drive box regardless of what size of the hard drive box is and address a more flexibility to interface with various hard drive boxes.

### BRIEF DESCRIPTION OF THE DRAWINGS

FIG. 1 is a partially exploded perspective view of a detachable external hard drive enclosure in accordance with the present invention;

FIG. 2 is a perspective view of the detachable external hard drive enclosure in FIG. 1;

FIG. 3A is an exploded perspective view of the detachable external hard drive enclosure in FIG. 1;

FIG. 3B is another exploded perspective view of the detachable external hard drive enclosure in FIG. 1;

FIG. 4 is a top view of the detachable external hard drive enclosure in FIG. 2 excluding a top half case of a hard drive box and a top half case of a bridge device;

FIG. 5A is a partially enlarged top view of the detachable external hard drive enclosure in FIG. 4;

FIG. 5B is a partially enlarged and exploded top view of the detachable external hard drive enclosure in FIG. 4;

FIG. 6 is a partially exploded view of the detachable external hard drive enclosure in FIG. 4 in collaboration with a hard drive;

FIG. 7A is a schematic top view of a small bridge device connected with a large hard drive case in accordance with the present invention;

FIG. 7B is a schematic top view of a large bridge device connected with a small hard drive case in accordance with the present invention;

FIG. 8 is a perspective view of a conventional external hard drive enclosure;

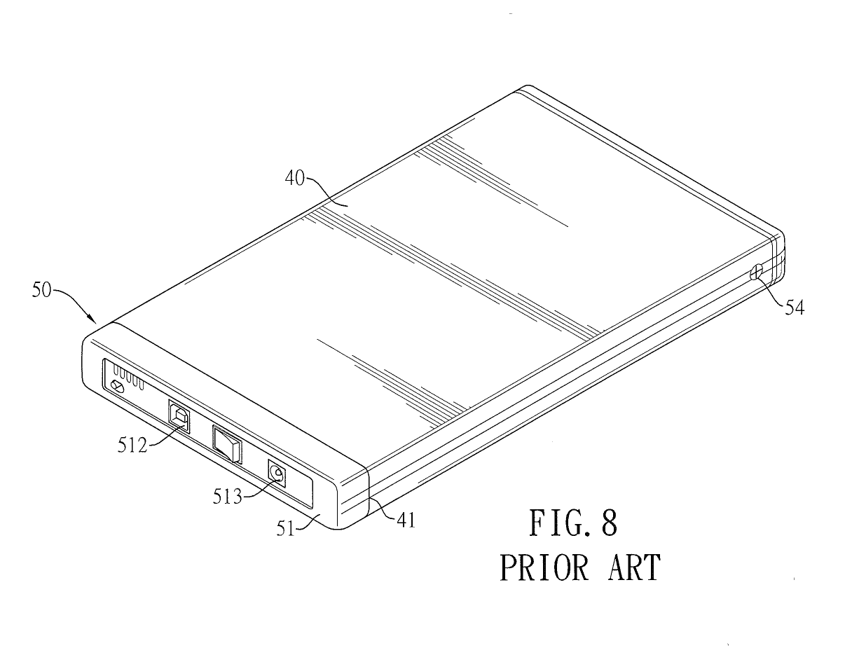

FIG. 9 is a top view of the conventional external hard drive enclosure in FIG. 8; and

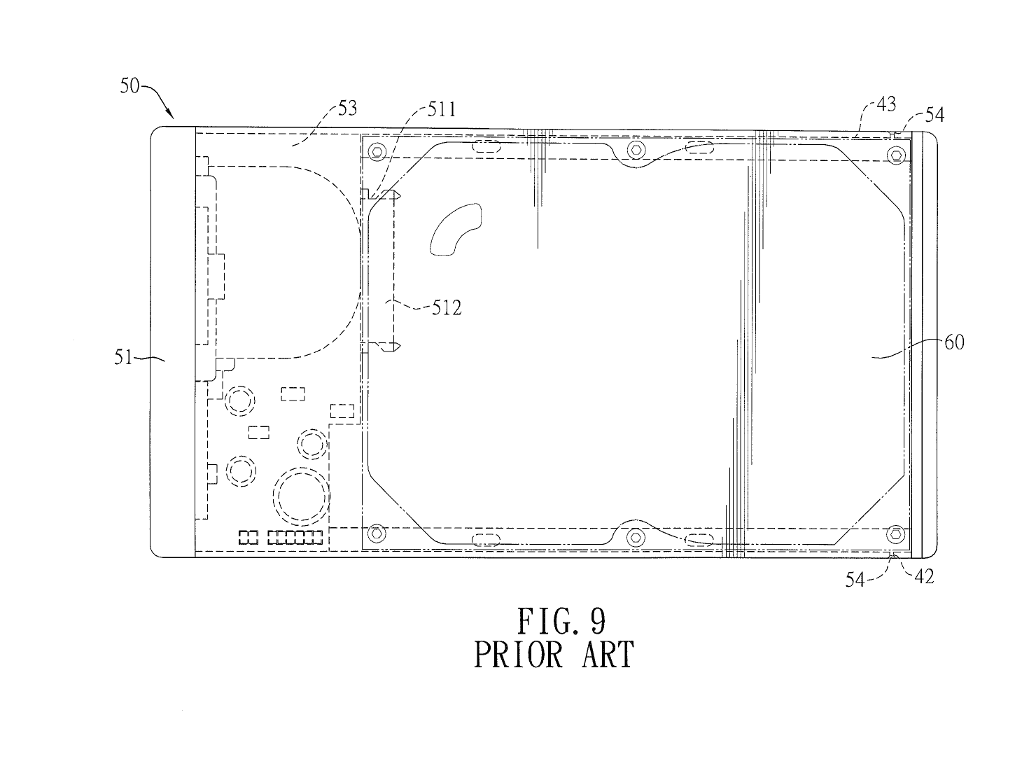

FIG. 10 is an exploded top view of the conventional external hard drive enclosure in FIG. 8.

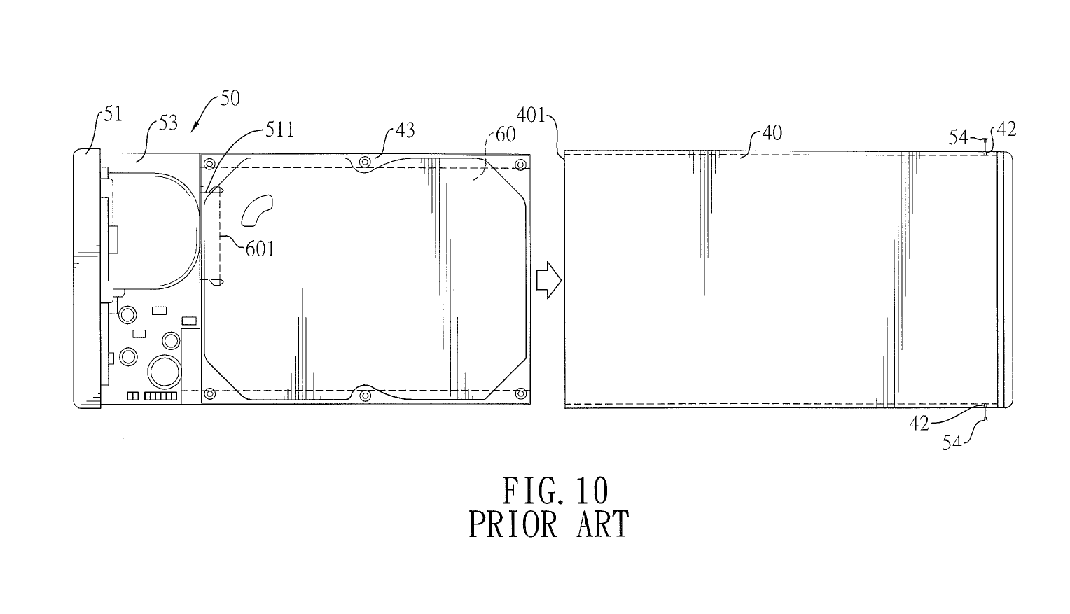

### DETAILED DESCRIPTION OF THE INVENTION

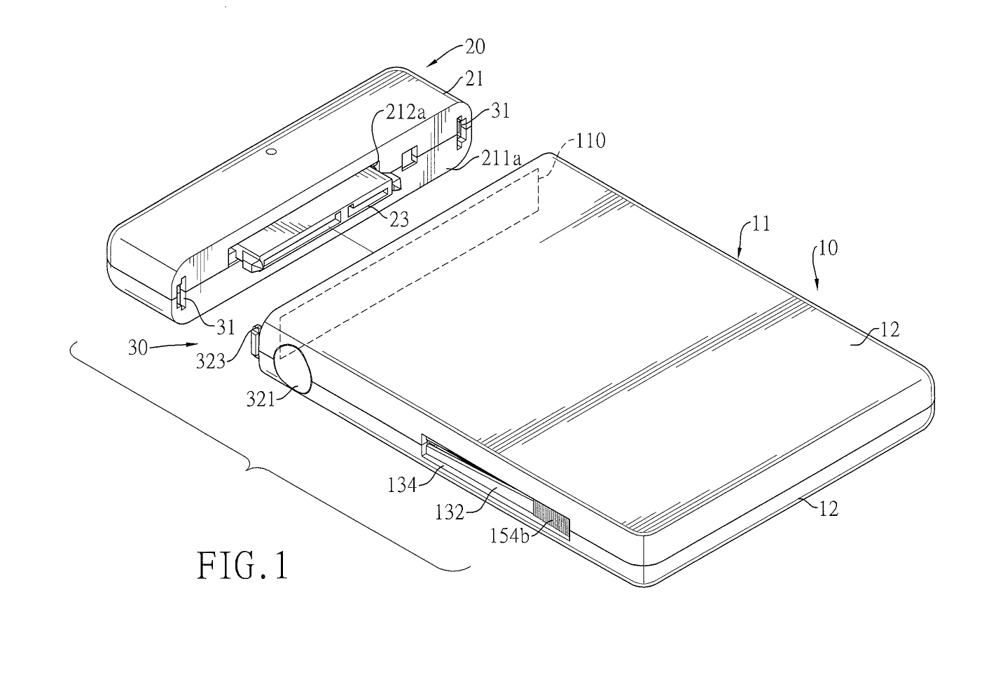

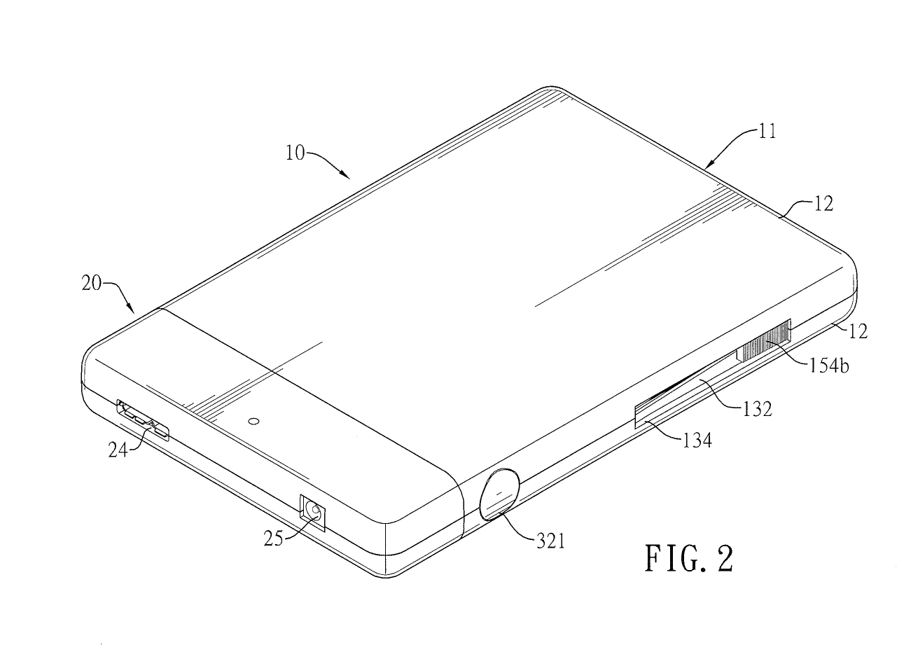

With reference to FIGS. 1 and 2, a detachable external hard drive enclosure in accordance with the present invention has a hard drive box 10, a bridge device 20 and an engagement mechanism 30. The engagement mechanism 30 serves to connect and engage the bridge device 20 and the hard drive case 10.

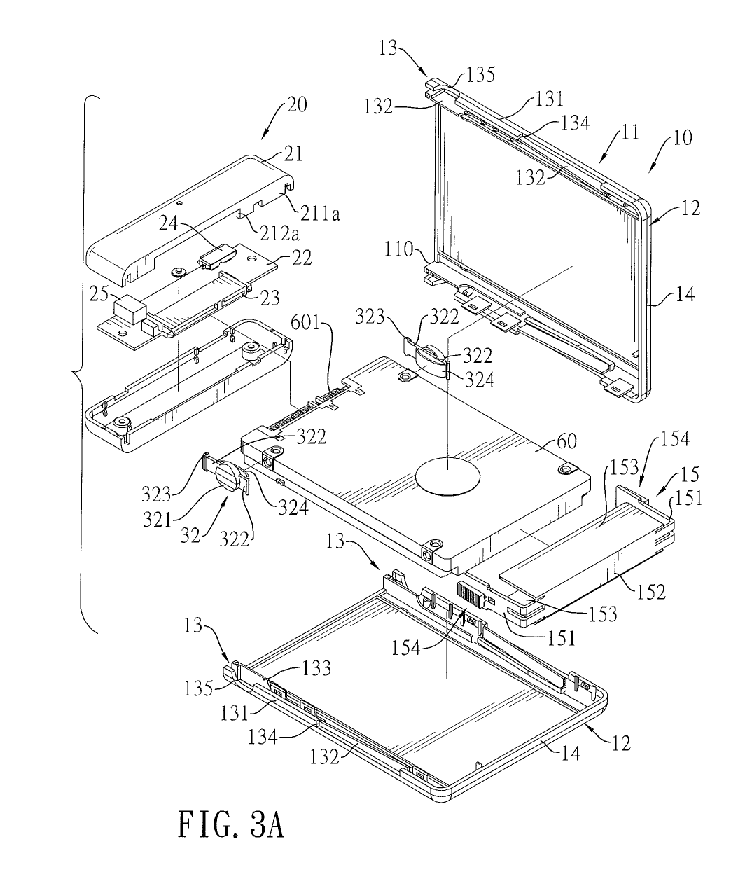

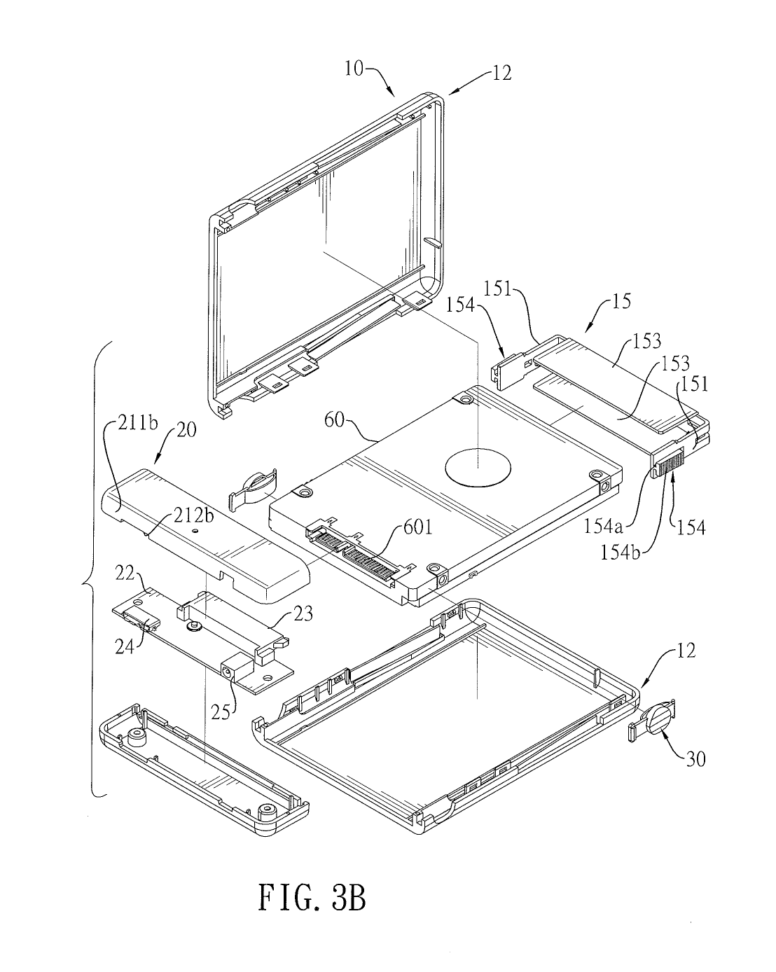

With reference to FIGS. 3A and 3B, the hard drive box 10 has a rectangular body 11 and a U-shaped slidable bracket 15.

The rectangular body 11 is hollow, has a front opening 110, and is foamed by two half cases 12. The front opening 110 is formed through a side of the hard drive box 10. The two half cases 12 are correspondingly connected with each other. Each of the two half cases 12 has two opposite long sidewalls 13 and a short sidewall 14. The short sidewall 14 faces the front opening 110. Each of the two long sidewalls 13 has an outer wall 131, a slanted guide plate 132 and an inner wall 133. The outer wall 131 has a semicircular groove 135 and a long channel 134. The semicircular groove 135 and the long channel 134 are formed through the outer wall 131 and are adjacent to the front opening 110 and the short sidewall 13 respectively. The slanted guide plate 132 is formed on each of the two half cases 12 to correspond to the corresponding long channel 134 and tilt down in a direction from the short sidewall 13 to the front opening 110 and from inside out. The inner wall 133 is parallel with the outer wall 131 and corresponds to a portion of the outer wall 131 without the long channel 134.

The U-shaped slidable bracket 15 is received in the rectangular body 11 and has two parallel walls 151, a transverse wall 152 and two T-shaped tabs 154. The two parallel walls 151 respectively abut the two long sidewalls 13 of each of the two half cases 12 and are slidable along the corresponding long sidewalls 13 in the rectangular body 11. The transverse wall 152 is parallel with the short sidewalls 14 of the rectangular body 11. Each of the two T-shaped tabs 154 is formed on and protrudes outwardly from an outside surface of the corresponding parallel wall 151 and has a horizontal portion 154a and a vertical portion 154b. The horizontal portion 154a is formed on and protrudes outwardly from the corresponding parallel wall 151, and is rested on and slidable along the slanted guide plate 132 of the corresponding long sidewall 13. The vertical portion 154b is perpendicularly formed on the horizontal portion 154a and is mounted within the long channel 134 of the corresponding outer wall 134. To steadily fix the hard drive 60, the U-shaped slidable bracket 15 further has two support boards 153 respectively mounted on a top edge and a bottom edge of the transverse wall 152 and respectively extending from the top edge and the bottom edge to the front opening 110.

The bridge device 20 has a housing 21, a control circuit board 22, a hard drive port 23, at least one computer port 24 and a power input port 25.

The housing 21 has a first side 211b, a second side 211a, three through slots 212a, 212b, 212b′. The second side 211a faces the front opening 110 of the rectangular body 11 and is opposite to the first side 211b. One of the through slots 212a is formed through the second side 211a, and two other through slots 212b, 212b′ are formed through the first side 211b of the housing 21. In the present embodiment, the housing 21 has two half cases correspondingly connected with each other.

The control circuit board 22 is mounted inside the housing 21. The hard drive port 23 is mounted inside the housing 21, is electrically connected with the control circuit board 22, protrudes beyond the housing 21 through the through slot 212a on the second side 211a, and is adapted to connect with an electrical connector 601 of the hard drive 60.

The at least one computer port 24 is mounted inside the housing 21, is electrically connected with the control circuit board 22, protrudes beyond the housing 21 through the through hole 212b on the first side 211b of the housing 21, and is adapted to connect with an external computer.

The power input port 24 is mounted inside the housing 21 and is electrically connected with the control circuit board 22, protrudes beyond the housing 21 through the through slot 212b′ on the first side 211b of the housing 21, and is adapted to connect with an external power source to supply an operating power of the control circuit board 22.

The engagement mechanism 30 in the present embodiment has two engagement slots 31 and two resilient buttons 32. The two engagement slots 31 are respectively formed through two opposite locations of the second side 211a of the housing 21 of the bridge device 20. Each of the two resilient buttons 32 is received between the outer walls 131 and the inner walls 133 of the corresponding long sidewalls 13 of the two half cases of the rectangular body 11 of the hard drive box 10 and corresponds to the semicircular grooves 135 of the corresponding outer walls 131. Each of the resilient button 32 has a circular button 321, two positioning arms 322, a fastener 323 and a resilient arc piece 324. The circular button 321 is received in and protrudes beyond the corresponding semicircular grooves 135 of the two half cases 12 of the hard drive box 10. The two positioning arms 322 are oppositely formed on the circular button 321 and protrude outwardly to be sandwiched by the outer wall 133 and the inner wall 131 of the corresponding long sidewall 13. The fastener 323 is formed on and protrudes outwardly from the positioning arm 322 adjacent to the front opening 110, protrudes beyond the front opening 110, and corresponds to the corresponding engagement slot 31. The resilient arc piece 324 takes a form of arch band, has two ends respectively formed on the two positioning arms 322 and abuts against the corresponding inner walls 133 of the two half cases 12.

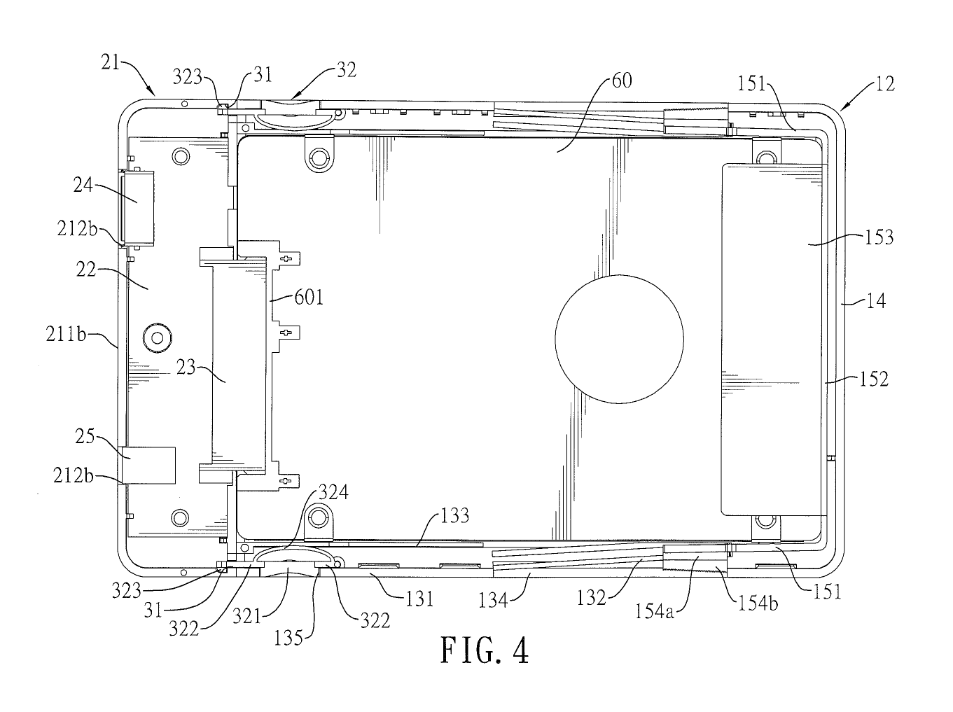

With reference to FIG. 4, as the two fastener 323 of the two resilient button 32 protrude beyond the front opening 110 of the hard drive box 10 and respectively correspond to the two engagement slots 31 on the housing 21 of the bridge device 20, if the bridge device 20 is intended to engage the hard drive box 10, the two resilient buttons 32 protruding beyond the hard drive box 10 are inserted into the corresponding engagement slots 31. After the two fasteners 323 are inserted into the corresponding engagement slots 31, the corresponding resilient buttons 32 are released and the resilient arc pieces thereof provide a restoring elastic force to make the two fasteners 323 further engage in an inside wall of the housing 21 of the bridge device 20. By now, the bridge device 20 covers the front opening 110 of the hard drive box 10 and engages the hard drive box 10.

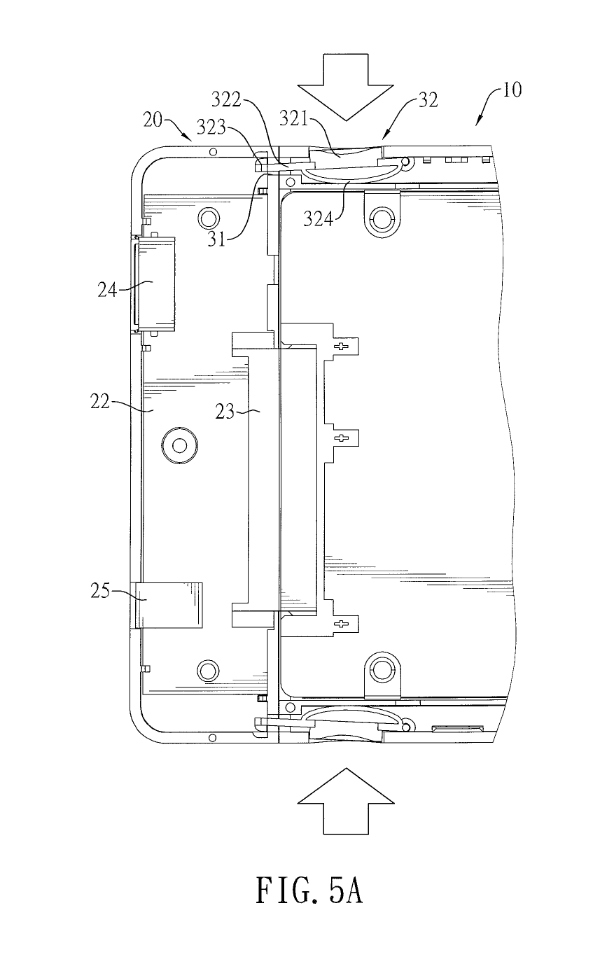

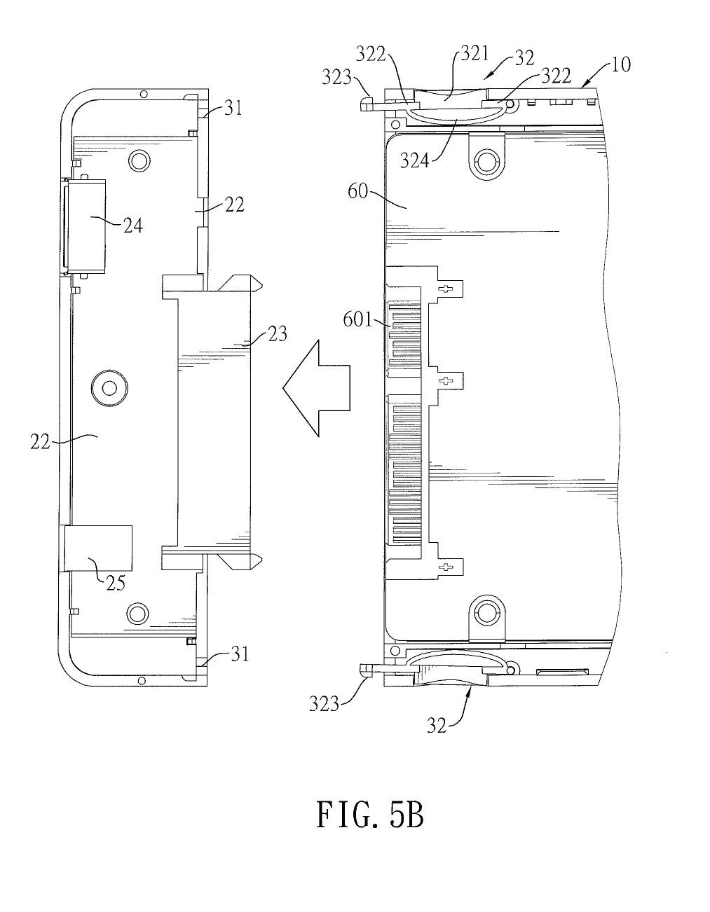

Similarly, with reference to FIGS. 5A and 5B, if the bridge device 20 is intended to disengage from the hard drive box 10, the two resilient arc pieces 324 are pressed inwardly against the corresponding inner walls 133. The reaction force compresses both ends of each of the two resilient arc pieces 324 to push the two positioning arms 322 outwardly. As a result, after aligning with the corresponding engagement slots 31, the two fasteners 323 can be removed from the housing 21 of the bridge device 20.

With reference to FIG. 4, when the hard drive is intended to be mounted, the hard drive 60 with the electrical connector 601 protruding beyond the front opening 110 of the hard drive box 10 is inserted into the front opening 110 and is pushed all the way rearwardly until the transverse wall 152 of the U-shaped slidable bracket 15 contacts with the short sidewall 14. Meanwhile, the vertical portion 154b of the T-shaped tab 154 is moved rearwardly within the corresponding long channel 134, and the hard drive 60 is completely received in the hard drive box 10. Since the electrical connector 601 of the hard drive 60 protrudes beyond the front opening 110, whenever the bridge device 20 engages the hard drive box 10 with the engagement mechanism 30, the exposed hard drive port 23 facing the front opening 110 also engages and electrically connects with the electrical connector 601 of the hard drive 60.

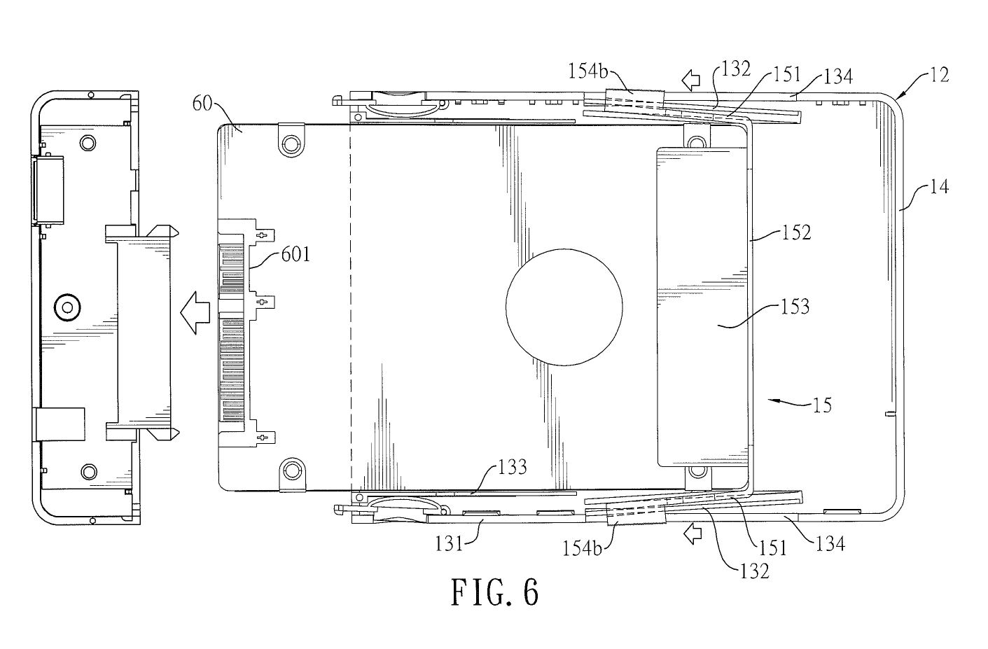

With reference to FIG. 6, when the hard drive 60 is intended to be removed, the bridge device 20 first disengages from the hard drive box 10 by simultaneously pressing the two resilient buttons 32 and moving them forwardly. The vertical portion 154b of each of the two T-shaped tabs 154 is moved toward the front opening 110, and the horizontal portion 154a integrally formed on the vertical portion of 154b of the corresponding T-shaped tab 154 of the U-shaped slidable bracket 15 drags the transverse wall 152 to push the hard drive 60 out of the front opening 110. As the vertical portion 154b of the T-shaped tab 154 is guided by the corresponding slanted guide plate 132 to slide forwardly and the slanted guide plate 132 orients in an inside-out direction, the corresponding parallel wall 151 integrally formed with the T-shaped tab 154 is also guided to orient in an inside-out direction. Accordingly, a gap existing between each of the two parallel walls 151 and the hard drive 60 facilitates the removal of the hard drive 60 from the hard drive box 10.

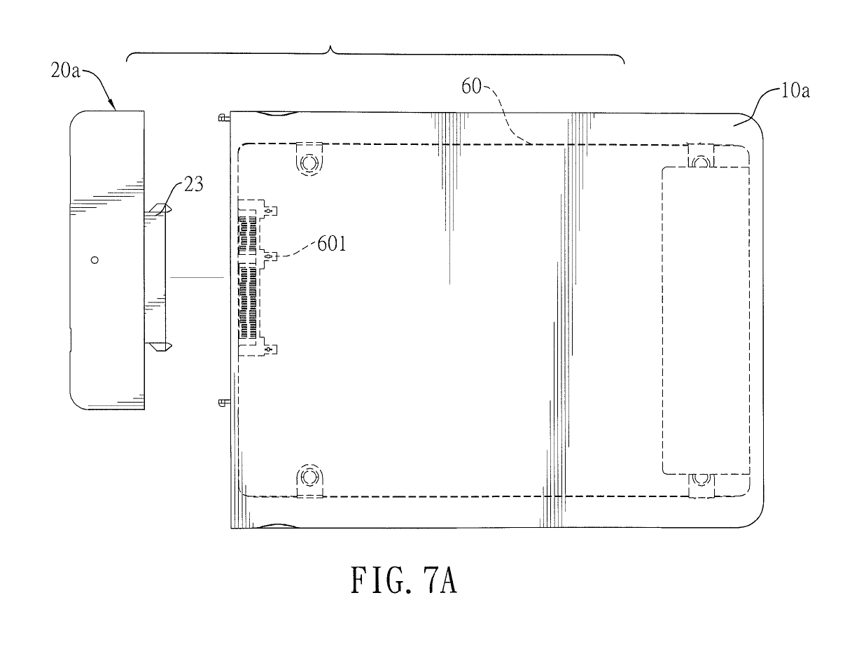

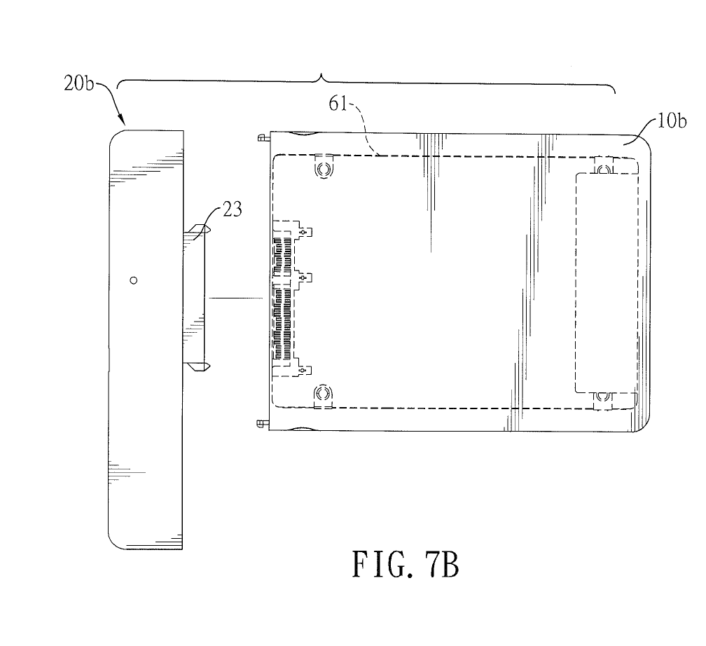

Instead of being securely connected with the bracket inside the hard drive box, the bridge device 20 of the detachable external hard drive enclosure in accordance with the present invention can directly engage the hard drive box without requiring to screw the bridge device and the hard drive box, thereby facilitating users to more conveniently mount and dismount a hard drive. Besides, the bridge device of the present invention pertains to a standalone product having the flexibility to adapt to hard drive boxes having different sizes. With reference to FIG. 7A, a 2.5″ bridge device 20a engages a 3.5″ hard drive box 10a. With reference to FIG. 7B, a 3.5″ bridge device 20b engages a 2.5 hard drive box 10b. Therefore, the bridge device 20a, 20b of the present invention is not limited by the compatibility concern with the size of hard drive box and is more convenient in use than the conventional external hard drive enclosure.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A detachable external hard drive enclosure, comprising:
a hard drive box having a front opening formed through a side of the hard drive box and adapted to receive a hard drive in the hard drive box;
a bridge device having:
a housing having a first side and a second side facing to the front opening and being opposite to the first side;
a control circuit board mounted inside the housing;
a hard drive port mounted inside and protruding beyond the second side of the housing and electrically connected with the control circuit board;
at least one computer port mounted inside and protruding beyond the first side of the housing, and electrically connected with the control circuit board; and
a power input port mounted inside and protruding beyond the first side of the housing, and electrically connected with the control circuit board; and
an engagement mechanism mounted on the side of the hard drive box having the front opening and the second side of the bridge device for the bridge device to engage the hard drive box.

2. The detachable external hard drive enclosure as claimed in claim 1, wherein the engagement mechanism comprises:
two engagement slots respectively formed through two opposite locations of the side facing the front opening of the hard drive box; and
two resilient buttons, each received in the hard drive box, and having a fastener formed thereon, protruding beyond the front opening, and corresponding to and engaging the corresponding engagement slot.

3. The detachable external hard drive enclosure as claimed in claim 2, wherein the hard drive box has a rectangular body formed by two half cases correspondingly connected with each other, each of the two half cases has:
a short sidewall facing the front opening; and
two opposite long sidewalls, each having:
an outer wall having:
a semicircular groove formed through the outer wall, being adjacent to the front opening, and corresponding to the corresponding resilient button; and
a long channel formed through the outer wall and being adjacent to the short sidewall;
a slanted guide plate formed on each of the two half cases to correspond to the corresponding long channel and tilts down in a direction from the short sidewall to the front opening and from inside out; and
an inner wall being parallel with the outer wall and corresponding to a portion of the outer wall without the long channel.

4. The detachable external hard drive enclosure as claimed in claim 3, wherein each of the two resilient buttons is received between the outer walls and the inner walls of the corresponding long sidewalls of the two half cases of the rectangular body of the hard drive box, and further has:
a circular button received in the corresponding semicircular grooves of the two half cases and protruding beyond the hard drive box;
two positioning arms oppositely formed on and protruding outwardly from the circular button and received between the outer wall and the inner wall of the corresponding long sidewall; and
a resilient arc piece taking a form of an arch band and having two ends respectively formed on the two positioning arms and abuts against the corresponding inner walls of the two half cases.

5. The detachable external hard drive enclosure as claimed in claim 3, wherein the hard drive box further has a U-shaped slidable bracket received in the rectangular body and having:
two parallel walls respectively abutting the two long sidewalls and are slidable along the corresponding long sidewalls of the rectangular body;
a transverse wall being parallel with the short sidewalls of the rectangular body; and
two T-shaped tabs, each formed on and protruding outwardly from an outside surface of the corresponding parallel wall and has:
a horizontal portion formed on and protrudes outwardly from the corresponding parallel wall, and rested on and slidable along the slanted guide plate of the corresponding long sidewall; and
a vertical portion perpendicularly formed on the horizontal portion and mounted within the long channel of the corresponding outer wall.

6. The detachable external hard drive enclosure as claimed in claim 4, wherein the hard drive box further has a U-shaped slidable bracket received in the rectangular body and having:
two parallel walls respectively abutting the two long sidewalls and are slidable along the corresponding long sidewalls of the rectangular body;
a transverse wall being parallel with the short sidewalls of the rectangular body; and
two T-shaped tabs, each formed on and protruding outwardly from an outside surface of the corresponding parallel wall and has:
a horizontal portion formed on and protrudes outwardly from the corresponding parallel wall, and rested on and slidable along the slanted guide plate of the corresponding long sidewall; and
a vertical portion perpendicularly formed on the horizontal portion and mounted within the long channel of the corresponding outer wall.

7. The detachable external hard drive enclosure as claimed in claim 5, wherein the U-shaped slidable bracket further has two support boards respectively mounted on a top edge and a bottom edge of the transverse wall and respectively extending from the top edge and the bottom edge to the front opening.

8. The detachable external hard drive enclosure as claimed in claim 6, wherein the U-shaped slidable bracket further has two support boards respectively mounted on a top edge and a bottom edge of the transverse wall and respectively extending from the top edge and the bottom edge to the front opening.

9. A bridge device for an external hard drive box having a front opening, the bridge device comprising:
a housing adapted to connect with the front opening of the external hard drive box and engage the detachable external hard drive enclosure, and having:
a first side;
a second side facing to the front opening and being opposite to the first side; and
two through slots formed through the first side and one through hole formed through the second side of the housing;
a control circuit board mounted inside the housing;
a hard drive port mounted inside the housing, electrically connected with the control circuit board, protruding beyond the housing through the through slot on the second side, and adapted to engage with an electrical connector of an external hard drive;
at least one computer port mounted inside the housing, electrically connected with the control circuit board, protruding beyond the housing through one of the through slots on the first side, and adapted to connect with an external computer;
a power input port mounted inside the housing, electrically connected with the control circuit board, protruding beyond the housing through the other of the through slots on the first side, and adapted to connect with an external power source to supply an operating power to the control circuit; and
an engagement mechanism mounted on the second side of the housing and adapted to connect with the hard drive box.

10. The bridge device as claimed in claim 9, wherein the engagement mechanism is two engagement slot formed through two opposite locations of the second side of the housing.

11. The bridge device as claimed in claim 9, wherein the housing is formed by two half cases correspondingly connected with each other.
